(19) United States
(12) Patent Application Publication
(10) Pub. No.: US 2022/0134507 A1
(43) Pub. Date: May 5, 2022

(54) CHEMICAL MECHANICAL POLISHING PAD HAVING PATTERN SUBSTRATE

(71) Applicant: KOREA INSTITUTE OF INDUSTRIAL TECHNOLOGY, Cheonan-Si Chungcheongnam-do (KR)

(72) Inventors: Hyoung Jae KIM, Busan (KR); Do Yeon KIM, Busan (KR); Tae Kyung LEE, Yangsan-si Gyeongsangnam-do (KR); Pil Sik KANG, Busan (KR)

(21) Appl. No.: 17/536,358

(22) Filed: Nov. 29, 2021

Related U.S. Application Data
(63) Continuation of application No. PCT/KR2020/006781, filed on May 26, 2020.

(30) Foreign Application Priority Data
May 29, 2019 (KR) 10-2019-0063360
May 29, 2019 (KR) 10-2019-0063372
May 29, 2019 (KR) 10-2019-0063380
May 11, 2020 (KR) 10-2020-0055933

(51) Int. Cl. B24B 37/26; B24B 37/04

(52) U.S. Cl. CPC B24B 37/26; B24B 37/044

(57) ABSTRACT

The present invention relates to a chemical mechanical polishing pad having a pattern structure. The configuration of the present invention provides a chemical mechanical polishing pad having a pattern structure including a polishing pad configured to polish a wafer placed thereon; and a plurality of figure units formed on the polishing pad and formed to protrude from an upper portion of the polishing pad. The figure units are formed to have a predetermined contact area ratio and a predetermined circumferential length per unit area which correspond to a target polishing characteristic.

### TECHNICAL FIELD

The present invention relates to a chemical mechanical polishing pad, and more particularly, to a chemical mechanical polishing pad having a pattern structure to have uniform polishing performance.

### BACKGROUND ART

The chemical mechanical polishing (CMP) process is a process for processing a substrate (wafer, etc.) to be processed while applying pressure and rotation to the surface of a pad, which is a rotating counterpart, and for polishing the surface of the substrate by supplying polishing liquid.

A conventional chemical mechanical polishing process generally uses a plate-like polymer as a polishing pad. Specifically, a conventional polishing pad uses a pad material having pores, abrasives, fibers, etc. or a polymer having a combination thereof.

In order to maintain polishing performance during polishing, a topography must be formed on the surface of the polishing pad by scratching the surface of the pad by using a rough conditioning plate with diamond particles attached thereto. The conventional polishing pad can have polishing performance by continuously maintaining topography or surface roughness only in this way.

On the surface of the polymer pad, grooves are formed along the trajectory of the movement of the diamond cutting particles through the conditioning process, and protrusions are formed in the region where the diamond particles do not pass, resulting in irregularities.

Among these grooves and protrusions, the grooves serve as a supply path for the polishing liquid, and the protrusions function to perform direct polishing by contacting a substrate to be polished or a wafer or various polishable substrates that are not limited thereto.

Since polishing performance is determined according to the density and size of the grooves and protrusions, the polishing performance can be uniformly maintained only when conditioning is continuously performed during polishing.

However, the conventional conditioning process has several problems.

First, these grooves are generally formed into a V-shape by a conical structure in the shape of a diamond particle, and conversely, the protrusions are generally formed in a conical triangular shape under the influence of diamond particle.

If polishing continues without conditioning, gradual wear of the projections proceeds. Accordingly, a phenomenon in which a real contact area with a polishing substrate is increased due to the wear of the conical protrusions proceeds, while the depths of the V-shaped grooves gradually decrease, and the supply of new polishing liquid decreases, thereby reducing overall polishing performance.

In addition, the conditioning process includes various variables such as the size, density, size distribution of the diamond of the conditioner, and the shape of the conditioner, as well as the rotational speed, pressure, sweep profile, and stability of the conditioning device. Thus, disadvantageously, it is difficult to maintain the projections and grooves of the polishing pad under the constant conditions all the time. Among these, the conditioner is consumables and must be replaced continuously, so it is difficult to expect consistent performance all the time.

In addition, the conventional pad has a problem in that it is difficult to adjust the shape and size of the protrusions to suit specific polishing conditions. For example, a specific surface topography may be required in order to obtain optimal polishing characteristics depending on the size, density, and material of the irregularities on the surface of a substrate to be processed, but it is difficult to obtain an appropriate target performance by only using a conditioning plate with a diamond. It is difficult to control the topography or surface roughness of the polishing pad because it is formed by a complex process that is determined by the size, density, size distribution of the diamond of the conditioner, the shape of the conditioner, the rotational speed, pressure, sweep profile, and stability of the conditioning device in the conditioning process.

Therefore, it is not easy to form a structure with a high density of protrusions per unit area on the polishing pad or to arbitrarily control and form a protrusion structure having a low density per unit area. In addition, forming a surface protrusion structure in a desired shape is difficult since the conditioning the sizes of the protrusions in a unit area to be large or small depends only on the conditioning process.

In addition, in order to manufacture a device used in a semiconductor process, elements and wires of various sizes and depths are formed on the surface of a wafer. Accordingly, surface irregularities having various widths, lengths, heights, and densities are formed on the surface of the wafer, and the CMP process is ultimately intended to planarize such surface irregularities. However, as described above, the conditioning process alone is insufficient to produce an optimal pad surface roughness or topography corresponding to various surface irregularities.

Accordingly, a need for the polishing pad having a controlled surface topography capable of responding to various surface irregularities as described above in a semiconductor process or a precision polishing process is increasing, and a need for a stable pad in which the cross-section topography of the pad does not change over time is also increasing. In addition, there is an increasing technical demand for freely designing and manufacturing such pads.

Accordingly, conventionally, as in Korean Patent Publication No. 10-2016-0142346, attempts have been made to make and use pre-formed standardized protrusions and grooves on the pad surface, but these attempts are merely limited to the area for the size and height of the projections and grooves. This type of pad design has a limit as a method for more clearly controlling the polishing characteristics, and a method that can more systematically respond to industrial demands corresponding to various polishing rates and flatness requirements is required.

On the other hand, FIG. 22 is an exemplary cross-sectional view showing a conventional polishing pad. As shown in FIG. 22, a conventional polishing pad 1 is composed of a pad made of a single material and is difficult to polish by following the shape of the wafer.

That is, there is a need for a polishing pad that performs polishing while following the surface shape of the wafer.
<Patent Document> Korean Patent Publication No. 10-2016-0142346

### DETAILED DESCRIPTION OF INVENTION

### Technical Problem

An object of the present invention for solving the above problems is to provide a chemical mechanical polishing pad having a pattern structure for improving the followability of a wafer surface and having uniform polishing performance.

The technical problem to be achieved by the present invention is not limited to the technical problems mentioned above, and other technical problems that are not mentioned can be clearly understood by those of ordinary skill in the technical field to which the present invention belongs from the following description.

### Solution to Problem

In order to achieve the above object, the configuration of the present invention provides a chemical mechanical polishing pad having a pattern structure, including a polishing pad configured to polish a wafer placed thereon, and a plurality of figure units formed on the polishing pad and formed to protrude from an upper portion of the polishing pad, where the figure units are formed to have a predetermined contact area ratio and a predetermined circumferential length per unit area which correspond to a target polishing characteristic.

In an embodiment of the present invention, the contact area ratio may be a value obtained by dividing a total protruding area (Aᵤ) of figure units of the plurality of figure units included in an inspection area by the inspection area (A₀) in a plan view.

In an embodiment of the present invention, the circumferential length per unit area may be a value obtained by dividing a total circumferential length (Lₜ) of the figure units included in the inspection area by the inspection area (A₀).

In an embodiment of the present invention, the contact area ratio may be 1.0% to 80.0%, and the circumferential length per unit area may be 1 mm/mm² to 250 mm/mm².

In an embodiment of the present invention, the figure units may include at least one type of a single figure part, a continuous figure part, and a set figure part, the single figure part is surrounded by one single closed curve, the continuous figure part is formed by a continuous line without the single closed curve and is composed of a minimum unit of repetition of the continuous line, and the set figure part is composed of a set of a plurality of the single figure parts adjacent to each other that is a minimum unit of repetition.

In an embodiment of the present invention, the single figure part is provided in plural, and the figure units may be provided by uniformly and repeatedly arranging the single figure parts of the same shape on the polishing pad.

In an embodiment of the present invention, the figure units may be provided by uniformly and repeatedly arranging the single figure parts of different shapes on the polishing pad.

In an embodiment of the present invention, the figure units may be provided by irregularly and repeatedly arranging the single figure parts of different shapes on the polishing pad.

In an embodiment of the present invention, the figure units may be provided by repeatedly arranging the single figure parts of the same shape with different sizes on the polishing pad.

In order to achieve the above object, the configuration of the present invention provides a polishing device including a chemical mechanical polishing pad having a pattern structure.

### Advantageous Effects of Invention

The effect of the present invention according to the configuration as described above can uniformly maintain the polishing performance of a polishing pad.

In addition, according to the present invention, it is possible to increase the usage efficiency of polishing liquid by allowing the polishing liquid to be easily transferred to the upper portion of a figure unit.

In addition, according to the present invention, the polishing liquid is quickly spread over the entire surface of a pattern unit by a groove unit, and the polishing liquid does not easily flow out of the polishing pad by the arrangement of the pattern unit and the figure unit, so that usage efficiency can be further improved.

Further, according to the present invention, since a lower pad part is made of a softer material than that of an upper pad part, the followability of a wafer surface can be improved.

The effects of the present invention are not limited to the above effects, and should be understood to include all effects that can be inferred from the configuration of the invention described in the detailed description or claims of the present invention.

### BRIEF DESCRIPTION OF DRAWINGS

FIG. 1 is an exemplary plan view of a polishing pad according to an embodiment of the present invention.

FIG. 2 is an exemplary view of a figure unit according to an embodiment of the present invention.

FIG. 3 is an exemplary cross-sectional view of a single figure part according to an embodiment of the present invention.

FIG. 4 is an exemplary view showing a method of calculating an contact area ratio according to an embodiment of the present invention.

FIG. 5 is an exemplary view showing a method of calculating a circumferential length per unit area according to an embodiment of the present invention.

FIGS. 6 to 9 are exemplary views showing an arrangement of a figure unit according to an embodiment of the present invention.

FIGS. 10 and 11 are graphs showing a polishing amount according to a circumferential length per unit area according to an embodiment of the present invention.

FIG. 12 is an exemplary view showing the shape of a single figure part according to an embodiment of the present invention.

FIG. 13 is an exemplary view showing a pattern unit of a polishing pad according to an embodiment of the present invention.

FIG. 14 is an exemplary view showing a boundary between pattern units according to an embodiment of the present invention.

FIG. 15 is an enlarged exemplary view showing a boundary between pattern units according to an embodiment of the present invention.

FIG. 16 is an exemplary view showing the flow of a polishing liquid according to an embodiment of the present invention.

FIGS. 17 to 20 are exemplary views showing the shape and arrangement of a figure unit according to an embodiment of the present invention.

FIG. 21 is an exemplary view showing a groove unit according to an embodiment of the present invention.

FIG. 22 is an exemplary cross-sectional view showing a conventional polishing pad.

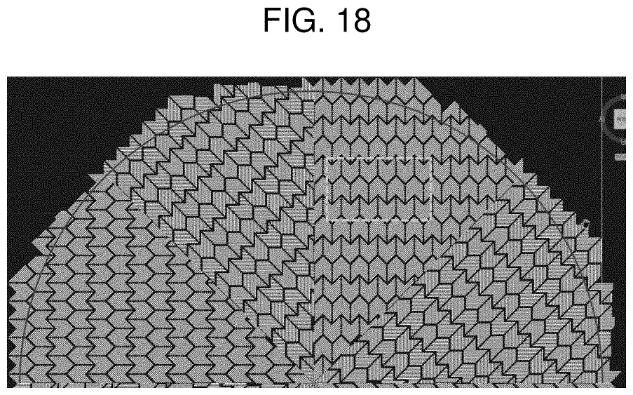

FIG. 23 is an exemplary cross-sectional view showing a chemical mechanical polishing pad having a pattern structure according to a first embodiment of the present invention.

FIG. 24 is an exemplary cross-sectional view showing a chemical mechanical polishing pad having a pattern structure according to a second embodiment of the present invention.

FIG. 25 is an exemplary cross-sectional view showing a chemical mechanical polishing pad having a pattern structure according to a third embodiment of the present invention.

FIG. 26 is an exemplary cross-sectional view showing a chemical mechanical polishing pad having a pattern structure according to a fourth embodiment of the present invention.

FIG. 27 is an exemplary cross-sectional view showing a chemical mechanical polishing pad having a pattern structure according to a fifth embodiment of the present invention.

FIG. 28 is an exemplary cross-sectional view showing a chemical mechanical polishing pad having a pattern structure according to a sixth embodiment of the present invention.

FIG. 29 is an exemplary cross-sectional view showing a chemical mechanical polishing pad having a pattern structure according to a seventh embodiment of the present invention.

FIG. 30 is a graph comparing the polishing rate performance of a conventional polishing pad and a chemical mechanical polishing pad having a pattern structure manufactured according to the present invention.

### BEST EMBODIMENT OF INVENTION

A best embodiment according to the present invention includes a polishing pad provided to polish a wafer placed thereon; and a plurality of figure units that is formed on the polishing pad and is formed to protrude upward from the polishing pad, and each of the figure units is formed to have an contact area ratio and a circumferential length per unit area which correspond to a target polishing characteristic.

### EMBODIMENTS OF INVENTION

Hereinafter, the present invention will be described with reference to the accompanying drawings. However, the present invention may be implemented in various different forms, and therefore is not limited to the embodiments described herein. In the drawings, parts irrelevant to the description are omitted in order to clearly describe the present invention, and similar reference numerals are assigned to similar parts throughout the specification.

Throughout the specification, when apart is said to be “connected (coupled, contacted, bonded)” with another part, this includes not only cases where it is “directly connected”, but also cases where it is “indirectly connected” with another member interposed therebetween. In addition, when a part “includes” a certain component, it means that other components may be further provided, rather than excluding other components unless specifically stated to the contrary.

The terms used in the present specification are only used to describe specific embodiments, and are not intended to limit the present invention. Singular expressions include plural expressions unless the context clearly indicates otherwise. In this specification, terms such as “comprise” or “have” are intended to designate the presence of features, numbers, steps, operations, components, parts, or a combination thereof described in the specification, and it should be understood that such terms do not preclude the possibility of presence or addition of one or more other features, numbers, steps, operations, components, parts, or combinations thereof.

Hereinafter, embodiments of the present invention will be described in detail with reference to the accompanying drawings.

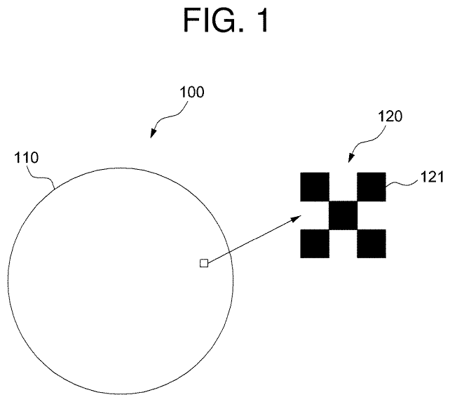

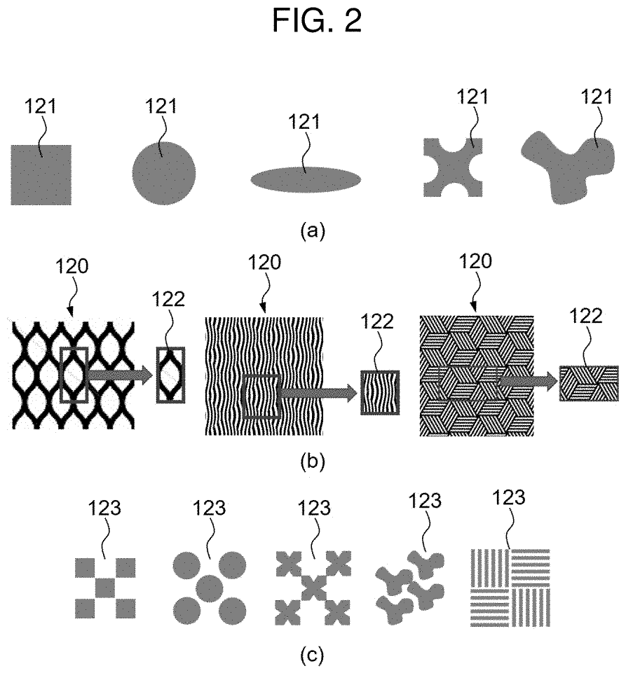

FIG. 1 is an exemplary plan view of a polishing pad according to an embodiment of the present invention, and FIG. 2 is an exemplary view of a figure unit according to an embodiment of the present invention.

As shown in FIGS. 1 and 2, the present invention may include a polishing pad 110 and a figure unit 120.

The polishing pad 110 may be provided to polish a wafer placed thereon, and may be provided in a disk shape. However, the shape of the polishing pad 110 is not limited thereto.

The polishing pad 110 may be made of a thermosetting polymer or a thermoplastic polymer.

The thermosetting polymer may include a polymer material such as polyurethane, polyamide, epoxy, acrylonitrile butadiene styrene (ABS), polyetherimide, and acrylate.

The thermoplastic polymer may include, as a thermoplastic elastomer (TPE), polyurethane, polyalkylene, polyethylene and polypropylene, polybutadiene, polyisoprene, polyalkylene oxide, polyethylene oxide, polyester, polyamide, polycarbohydrate, polystyrene. In addition, the thermoplastic polymer may be provided with any one of the above-described materials, or may be formed of a block copolymer or a polymer blend made of a combination of two or more of the above-described materials.

In addition, the thermoplastic polymer may include epoxy, phenol resin, amine, polyesters, urethane, silicone, acrylate, and mixtures and copolymers thereof, and as polymer materials, fluorene, phenylline, pyrene, azulene, naphthalene, acetylene, p-phenylene vinylene, pyrrole, carbazole, indole, azepine, aniline, thiophene, 3,4-ethylenedioxythiphene, p-phenylene sulfide, and a group consisting of combinations of two or more thereof may be included.

The figure unit 120 may be formed on the polishing pad 110 and may be formed to protrude toward an upper portion of the polishing pad 110. The figure unit 120 may be repeatedly formed in a constant shape on the polishing pad 110.

The figure unit 120 may be made of the same material as the polishing pad 110, and even if the material is the same, the figure unit may be made of the materials whose physical properties such as hardness or elastic modulus, loss modulus, storage modulus, and the like may be different. Also, if necessary, the figure unit 120 may be made of a material different from that of the polishing pad 110.

As shown in FIG. 2, the figure unit 120 may include a single figure part 121, a continuous figure part 122, and a set figure part 123.

The single figure part 121 may be defined as a figure surrounded by one single closed curve.

The continuous figure part 122 may be formed by a continuous line without the single closed curve, and be defined as a minimum unit of repetition of the continuous line.

The set figure part 123 may be defined as a set of a plurality of adjacent single figure parts 121 that is a minimum unit of distinguishable repetition.

The figure unit 120 may be formed to include any one of the single figure part, the continuous figure part, and the set figure part.

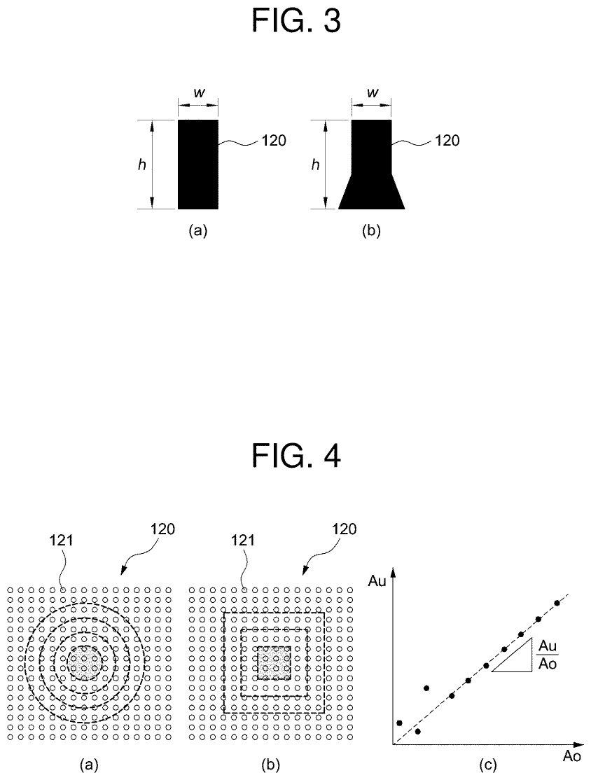

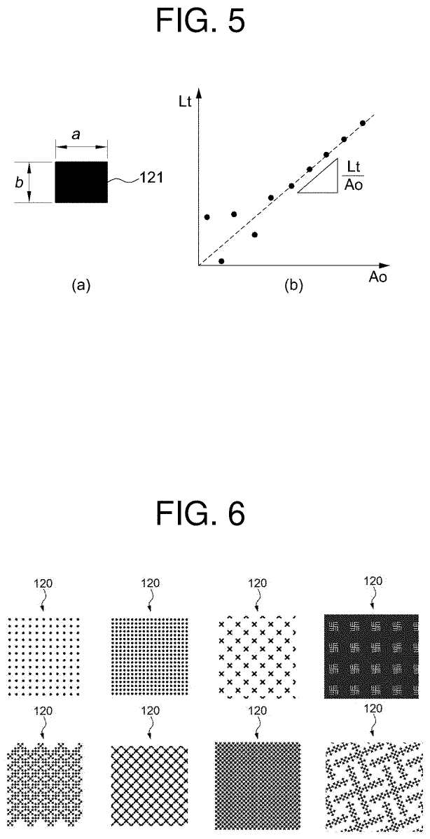

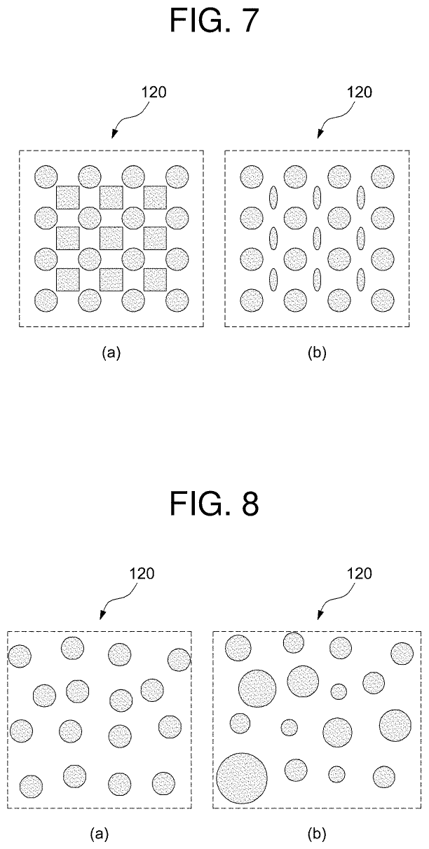

FIG. 3 is an exemplary cross-sectional view of a single figure unit according to an embodiment of the present invention, FIG. 4 is an exemplary view showing a method of calculating an contact area ratio according to an embodiment of the present invention, and FIG. 5 is an exemplary view showing a method of calculating a circumferential length per unit area according to an embodiment of the present invention.

With further reference to FIGS. 3 to 5, the figure unit 120 may be formed to have an contact area ratio and a circumferential length per unit area that correspond to a target polishing characteristic.

When defining a certain area of the surface on which a repeating pattern is engraved as an inspection area (A₀), the contact area ratio may be defined as a value that is obtained by dividing a total protruding area (Aᵤ) of the figure units 120 included in the inspection area (A₀) by the inspection area (A₀) in a plan view. That is, in this case, the total protruding area (Aᵤ) of the figure units 120 means the sum of the protruding areas of the single figure parts 121 and the continuous figure parts 122 included in the inspection area (A₀). Examples of the inspection area (A₀) are illustrated as broken lines in (a) and (b) of FIG. 4.

For example, as shown in FIG. 5, when the number of the single figure parts 121 in the inspection area is n and the size of an element figure is a×b, the value of the protruding area (Aᵤ) becomes n×(a×b).

The unit of the contact area ratio may be expressed as a dimensionless quantity or a percentage (%).

In another example, since the contact area ratio may vary depending on the size of the protruding areas (Aᵤ) of the figure unit 120 and the size of the inspection area (A₀), the contact area ratio (Aₐ) may be defined as a slope value in a linear correlation shown in a graph as in FIG. 4 when the protruding area (Aᵤ) included in the inspection area (A₀) is measured while increasing the size of the inspection area (A₀) at an arbitrary position of the arranged pattern.

The contact area ratio may be controlled to be 1.0% to 80.0%, or 1.0% to 30.0%, or 10.0% to 30.0%.

The circumferential length per unit area can be defined as a value that is obtained by dividing a total circumferential length (Lₜ) of the figure units 120 included within in the inspection area (A₀) by the inspection area (A₀). When there is the single figure part 121 illustrated in FIG. 5 and the number of the single figure parts 121 within the inspection area (A₀) is n, the circumference length of the single figure part 121 is defined as 2(a+b), and the total circumference length of the figure units 120 within the inspection area (A₀) is defined as 2n(a+b). In this way, when defining a certain area of the surface on which the repeated single figure part 121, continuous figure part 122, etc. are engraved as the inspection area (A₀), the circumferential length per unit area may be the value obtained by dividing the total circumferential length of all figure units 120 included in the area by the inspection area (A₀), and may have the basic unit of mm/mm². However, the unit system can be expressed in any way that is converted into units by dividing the length by the area.

For more accurate definition and consistent analysis of the circumferential length per unit area depending on the size of the figure unit 120 and the size of the inspection area (A₀), the circumferential length per unit area may be defined as a slope value in a linear correlation shown in a graph as in FIG. 5 when the total circumferential length (Lt) of the pattern included in the inspection area (A₀) is measured while increasing the size of the inspection area (A₀) at any position of the arranged pattern.

The circumferential length per unit area may be controlled to be 1 mm/mm² to 250 mm/mm² or 1 mm/mm² to 50 mm/mm².

It is preferable that the protrusion height of the figure unit 120 is controlled in the range of 0.001 mm to 1 mm, and the amount of change in the cross-sectional area in the vertical direction of the figure unit 120 is controlled in the range of 0 to 20%. Here, the amount of change in the cross-sectional area in the vertical direction means the amount of change in the cross-sectional area according to the vertical height of the figure unit 120.

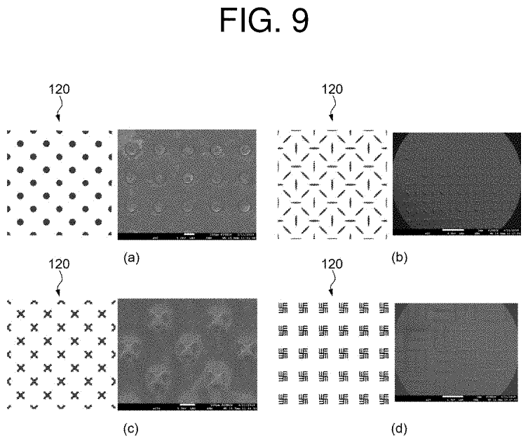

FIGS. 6 to 9 are exemplary views showing an arrangement of a figure unit according to an embodiment of the present invention.

As shown in FIGS. 6 to 9, the figure unit 120 may be provided by uniformly and repeatedly arranging the single figure part 121, continuous figure part 122, and set figure part 123 of the same shape on the polishing pad 110.

Alternatively, the figure unit 120 may be provided by uniformly and repeatedly arranging the single figure part 121, continuous figure part 122, and set figure part 123 of different shapes on the polishing pad 110.

Alternatively, the figure unit 120 may be provided by irregularly and repeatedly arranging the single figure part 121, continuous figure part 122, and set figure part 123 of different shapes on the polishing pad 110.

Alternatively, the figure unit 120 may be provided by repeatedly arranging the single figure part 121, continuous figure part 122, and set figure part 123 of the same shape with different sizes on the polishing pad 110.

On the other hand, when defining the correlation for the contact step between the wafer and the polishing pad 110, an apparent contact pressure (Pa) can be defined, and the apparent contact pressure can be defined as a value obtained by dividing the total load applied to the substrate by the total area of the substrate. This apparent contact pressure may be provided as a factor that controls the amount of polishing and other polishing characteristics by adjusting the total load that is generally applied to the substrate by a polishing device during polishing.

In addition, an apparent contact pressure on pattern (Ppa) can be defined, and the apparent contact pressure on pattern can be defined as a pressure when it is assumed that both the surface of the wafer and the upper portion of a protruding element figure are in contact. That is, it is defined as a value obtained by dividing the sum of the upper areas of the figure unit 120 under the area of the polishing pad 110 covered by the wafer by the total load applied to the wafer.

In addition, a real contact pressure (Pr) can be defined, and the real contact pressure is a value obtained by dividing the load applied to the wafer by the total area of the figure unit 120 actually in contact with the surface of the wafer. When the surface of the polishing pad is ideally flat and the surface of the wafer is ideally flat, the real contact pressure and the apparent contact pressure on pattern are the same, but the two values may be different due to flatness errors that may occur during the manufacturing process of the wafer and polishing pad 110.

The real polishing characteristics are greatly affected by the real contact pressure. If the real contact pressure is large, a polishing rate may increase. However, when polishing a soft substrate including a metal or a wafer, defects such as scratches can be left on the surface of the substrate as a result of the polishing particles contained in the polishing liquid. Therefore, the real contact pressure must be controlled at an appropriate level.

The soft metal may include copper, aluminum, tungsten, titanium, titanium nitride, tantalum, tantalum nitride, and the like, but is not limited to these materials. However, when polishing a substrate material having high hardness or a wafer, a high real contact pressure characteristic may be required, so it is not necessary to make the real contact pressure low.

Although it is not easy to control the apparent contact pressure on pattern only by conditioning in a general polishing pad, the present invention can control the contact area ratio as designed. Here, the substrate material having high hardness may include SiO², SiₓNₓ, SiC, etc., but is not limited thereto.

The characteristics of a proposed pad for polishing 100 are to control the contact area ratio and circumferential length per unit area of an element pattern in order to control polishing performance. That is, even if the wafer contacts the surface of the same polishing pad 110, the polishing characteristics can be actually controlled according to the contact area ratio and the circumferential length per unit area on the surface of the polishing pad 110.

That is, when designing the pad for polishing 100, the apparent contact pressure on pattern can be primarily adjusted by adjusting the wafer and the contact area ratio of the figure unit 120, and the circumferential lengths per unit area is designed to be different in the same contact area ratio, so that the polishing characteristics can be controlled.

Here, by adjusting the apparent contact pressure on pattern, scratches or excessive pressure that may occur on the surface of the wafer can be easily adjusted.

However, in the pad for polishing 100 having the same apparent contact pressure on pattern, it may additionally be necessary to more easily control the polishing characteristics by adjusting other factors such as a polishing rate. To this end, by adjusting the circumferential length per unit area in addition to the primarily determined contact area ratio, the polishing characteristics can be further controlled. This design process can also be implemented by determining the circumferential length per unit area first and adjusting the contact area ratio.

In addition, the flatness of the polishing pad 110 may not be uniform in manufacturing the pad for polishing 100. Thus, if the flatness of the polishing pad 110 is not good, only a part of the figure unit 120 on the polishing pad 110 is in contact with the wafer, or even if the entire figure unit 120 is in contact with the wafer, the uniformity of the pad may not be good. In this case, the apparent contact pressure on pattern and the real contact pressure may be different because a portion having a high real contact pressure and a portion having a low real contact pressure may exist. In order to compensate for such imperfections in the actual manufacturing process, the polishing pad 110 and the figure unit 120 may be made of the same material. However, preferably, they may be made of the same material having different physical properties, that is, hardness, elastic modulus, loss modulus, storage modulus, and the like.

In a more preferred embodiment, the difference between the apparent contact pressure on pattern and the real contact pressure may be reduced by designing the elastic modulus or hardness of the polishing pad 110 to be lower than the elastic modulus or hardness of the figure unit 120. In addition, the polishing pad 110 may be attached to a flat plate having a lower elastic modulus or hardness to reduce the difference between the apparent contact pressure on pattern and the real contact pressure.

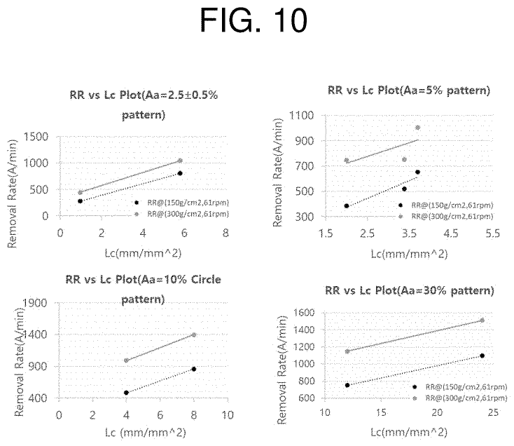

FIGS. 10 and 11 are graphs showing a polishing amount according to a circumferential length per unit area according to an embodiment of the present invention.

FIG. 10 is an experimental result conducted by changing the shape of the figure unit 120 and then making the circumferential lengths per unit area differently in the pad for polishing 100 on which the uniform figure unit 120 having the same contact area ratio is formed.

More specifically, FIG. 10 shows the experimental result of changing the apparent contact pressure using the pad for polishing 100 on which the figure unit 120 of a uniform pattern having the contact area ratio of 2.5%±0.5%, 5%, 10% and 30% is formed. As can be seen in FIG. 10, it can be seen that the polishing characteristic is consistently controlled when the circumferential length per unit area is changed even within the pad for polishing 100 on which each uniform pattern having the same apparent contact pressure on pattern is formed.

In addition, the experimental result of adjusting the contact area ratio and the circumferential length per unit area by using various patterns shown in FIG. 6 is shown in FIG. 11. The left graph of FIG. 11 is a result of polishing by changing the contact area ratio and the circumferential length per unit area using the circular figure unit 120, and it can be seen that a polishing rate is proportionally controlled according to the circumferential length per unit area.

In addition, the right graph of FIG. 11 shows the result of controlling the polishing rate by adjusting the circumferential length per unit area and the contact area ratio using not only the circle figure unit but also various figure units 120 illustrated in FIG. 6. It can be seen that the result is consistently applied not only to the circle shape but also to various shapes.

Therefore, in the polishing process in which defects such as scratches have to be prevented, the single figure part 121, continuous figure part 122 or set figure part 123 having various shapes and arrangements capable of controlling the circumferential length per unit area can be provided to increase the contact area ratio of the figure unit 120 while controlling other polishing characteristics such as the polishing rate.

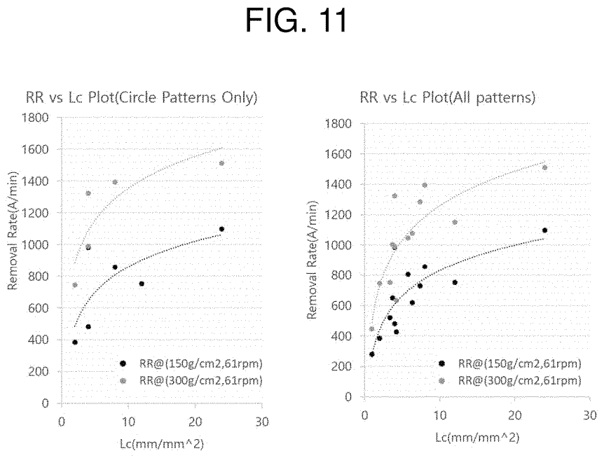

FIG. 12 is an exemplary view showing the shape of a single figure part according to an embodiment of the present invention.

In addition, the single figure part 121 of the figure unit 120 may be variously designed in the shapes shown in FIG. 12 in order to adjust the circumferential length per unit area for the same contact area ratio as an embodiment, but the size, arrangement density, shape, etc. thereof are not limited to the embodiments shown here.

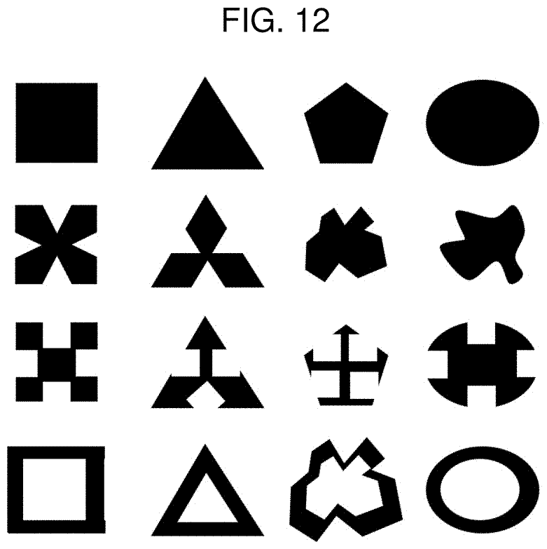

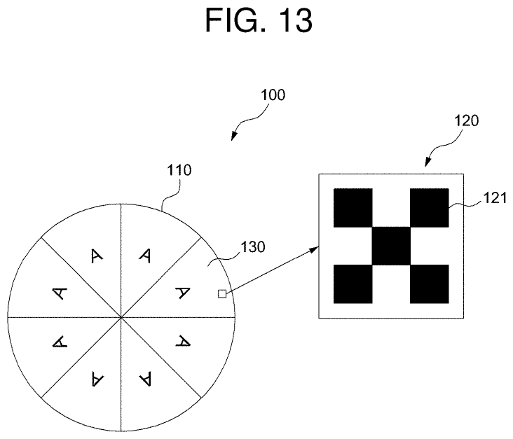

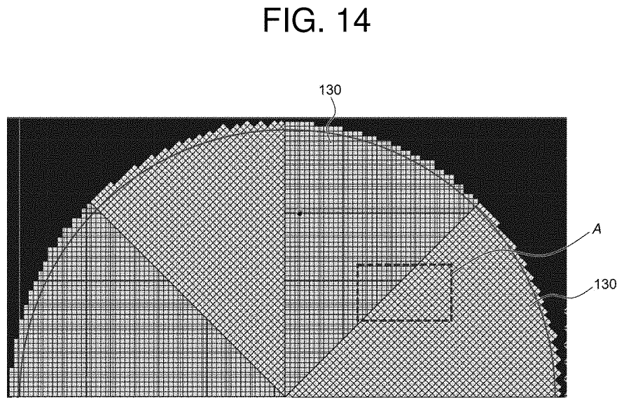

FIG. 13 is an exemplary view showing a pattern unit of a polishing pad according to an embodiment of the present invention. FIG. 14 is an exemplary view showing a boundary between pattern units according to an embodiment of the present invention, and FIG. 15 is an enlarged exemplary view showing a boundary between pattern units according to an embodiment of the present invention.

As shown in FIGS. 13 to 15, the pad for polishing 100 may further include a pattern unit 130.

The pattern unit 130 may be formed of a plurality of the figure units 120, and each of a plurality of pattern units 130 may have a sector shape on the polishing pad 110. Here, the sector shape is part of a circle made of the arc of the circle along with its two radii.

Specifically, the polishing liquid accommodated inside the figure unit 120 provided on the polishing pad 110 changes in a flow direction according to a rotation direction because the polishing process is a rotation process. Therefore, it is preferable that at least 3 pieces or more of the pattern units 130 are arranged on the polishing pad 110 in order to achieve a uniform polishing characteristic at all angles.

In other words, the pattern unit 130 may be provided by dividing the polishing pad 110 into a number such that the flow direction of the polishing liquid in each of the pattern units 130 in accordance with the rotation direction of the polishing pad 110 becomes the same in order to achieve the uniform polishing in which the polishing characteristic of the wafer satisfies within a preset error rate throughout the entire polishing pad 110.

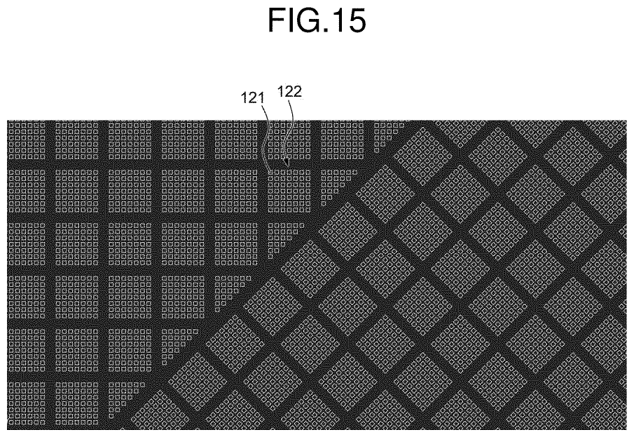

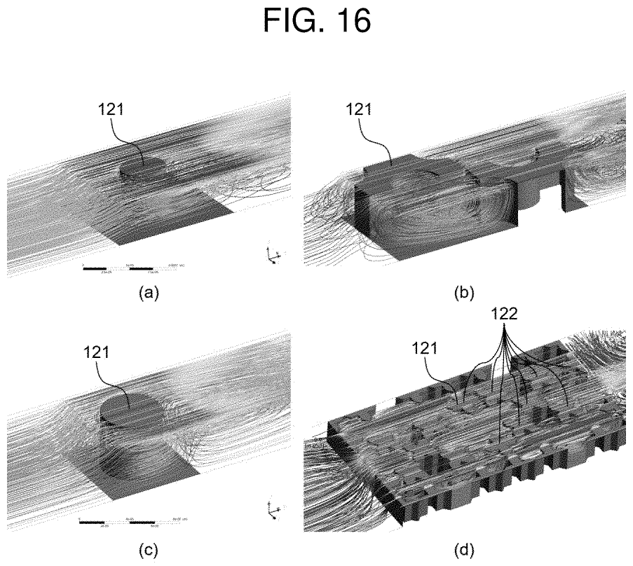

FIG. 16 is an exemplary view showing the flow of a polishing liquid according to an embodiment of the present invention, and FIGS. 17 to 20 are exemplary views showing the shape and arrangement of a figure unit according to an embodiment of the present invention.

As shown in FIGS. 16 to 20, the figure unit 120 constituting the pattern unit 130 can be arranged to have a flow resistance structure that allows the polishing liquid flowing in the rotation direction to move toward the upper portion of the figure unit 120.

To this end, the single figure part 121 constituting the continuous figure part 122 and the set figure part 123 of the figure unit 120 may be provided to have a flow resistance structure such as a v shape, a + shape, and a zigzag shape.

In addition, the pattern unit 130 and the figure unit 120 may be provided in a structure such that the polishing liquid is accommodated inside the figure unit 120, so that the polishing liquid is prevented from flowing out of the polishing pad 110.

That is, the arrangement of the figure unit 120 may be provided in a direction that prevents the polishing liquid from flowing out of the polishing pad 110 by centrifugal force.

The pattern unit 130 and the figure unit 120 provided with such a structure can increase the usage efficiency of the polishing liquid by increasing the time that the polishing liquid stays on the polishing pad 110.

In addition, as can be seen from the analysis result of the flow characteristic of the polishing liquid in FIG. 16, the analysis results of upper and lower left (a) and (c) are flow analysis results in case of a single circular figure, and the analysis results of upper and lower right (b) and (d) are flow analysis results in a set of figures in which the single figures are collected so as to interfere with the flow direction of a slurry.

As can be seen from this result, it is obvious that the flow resistance of the slurry during the flow of the slurry becomes greater when the set of figures is used than when the single figure is used. For this reason, the slurry participates more in the upper portion of the pattern, that is, the portion in contact with a subject to be processed. The amount of polishing can be further controlled by using such set of figures.

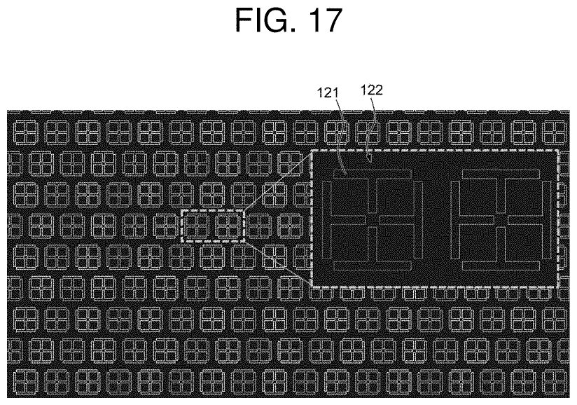

FIG. 21 is an exemplary view showing a groove unit according to an embodiment of the present invention.

As shown in FIG. 21, the pad for polishing 100 according to the present invention may further include a groove unit 140.

The groove unit 140 may be formed in the pattern unit 130 and may be provided in a groove shape to transfer the polishing liquid supplied to the pattern unit 130 to the front surface of the pattern unit 130.

The groove unit 140 may include a first groove 141, a second groove 142 and a third groove 143.

The first groove 141 may be radially formed along borders between the pattern units 130 to guide the polishing liquid in the direction from a center of the polishing pad 110 into an edge of the polishing pad 110. More specifically, the first groove 141 may be formed in a groove shape at a position corresponding to a line forming a radius of the polishing pad 110 of the pattern unit 130. The first groove 141 formed as described above may allow the polishing liquid to rapidly spread in the direction from the center of the polishing pad 110 into the edge of the polishing pad 110.

The pattern unit 130 may be formed to have 3 to 12 first grooves 141.

The second groove 142 may be formed in a concentric shape that forms a concentric circle with the polishing pad 110 so as to guide the polishing liquid along the concentric shape.

The second groove 142 provided as described above may guide the polishing liquid to rapidly spread along the concentric shape of the second groove 142.

The second groove 142 may be formed in plural, and a plurality of the second grooves 142 may be formed to have an interval of 0.5 mm to 5 mm from each other.

The third groove 143 may be formed to be inclined with respect to a direction tangential to the rotation direction of the polishing pad 110.

The third groove 143 may be formed to be inclined at +45 degrees to −45 degrees with respect to the tangent direction of the rotation direction of the polishing pad 110.

The first groove 141, the second groove 142, and the third groove 143 are provided to have a width of 0.1 mm to 2.0 mm, and may be formed to have a depth of 0.05 mm to 2.00 mm.

The groove unit 140 may be provided to have one or more of the first groove 141, the second groove 142, and the third groove 143.

The pad for polishing 100 according to the present invention prepared as described above can maintain a uniform polishing performance even if the figure unit 120 is worn by the wafer, and can easily control the polishing rate of the pad for polishing 100.

On the other hand, the polishing pad of the chemical mechanical polishing pad having a pattern structure according to the present invention is composed of an upper pad part 1100 and a lower pad part 1200. It is preferable that the lower pad part 1200 is formed of a soft material such that at least one physical property of hardness and elastic modulus is lower than that of the upper pad part 1100.

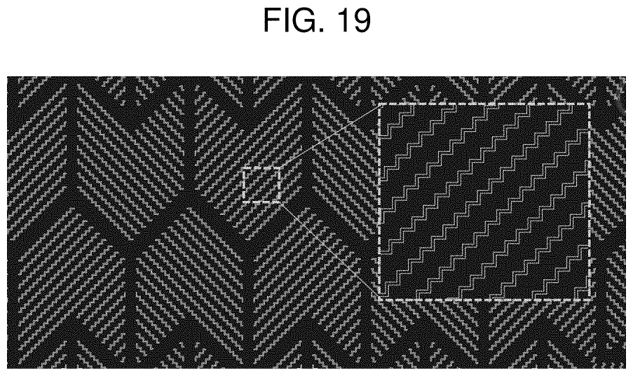

That is, in the chemical mechanical polishing pad having a pattern structure according to the first to third embodiments as shown in FIGS. 23 to 25, the upper pad part is formed directly on the lower pad part, so that the upper pad part and the lower pad part are made in an integrated state. An engraved mold is filled with a polymer and then frozen to form the upper pad part 1100. In this case, the engraved mold may be provided to form an engraved pattern having a shape corresponding to the pattern unit such that the pattern unit composed of the plurality of figure units 120 is formed on the upper pad part 1100.

Thereafter, before the upper pad part 1100 is completely hardened, the lower pad part 1200 is brought into close contact with the lower portion of the upper pad part 1100, and the upper pad part 1100 should be in a state in which the polymer filled in the engraved mold has not yet completely hardened.

Thereafter, the lower pad part 1200 and the upper pad part 1100 may be integrated by pressing and attaching the lower pad part 1200 toward the upper pad part 1100.

In this way, when the lower pad part 1200 is made of the same material as the upper pad part 1100, the lower pad part and the upper pad part can be easily integrated while being in close contact before the upper pad part 1100 is completely hardened. When the lower pad part 1200 is provided softer than the upper pad part 1100, polishing efficiency may be improved as the lower pad part 1200 is deformed in correspondence with the surface shape of the wafer.

In addition, the thickness of the upper pad part 1100 and the lower pad part 1200 excluding the figure unit 120 may be less than 4 mm.

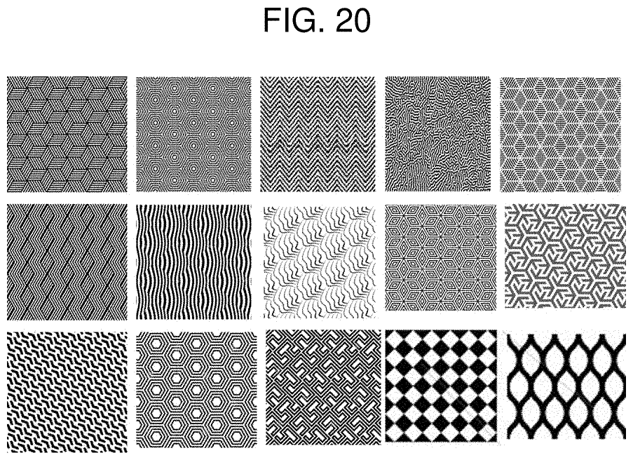

FIG. 24 is an exemplary view showing a chemical mechanical polishing pad having a pattern structure according to a second embodiment of the present invention.

Referring to FIG. 24, in the step of forming the upper pad part by filling and freezing a polymer in an engraved mold (S110), the engraved pattern formed in the engraved mold may be provided such that a gap region (G) in which the figure unit 120 is not formed is further formed between the plurality of pattern units.

In this case, the width of the gap region (G) may be formed to be 0.2 mm to 5 mm.

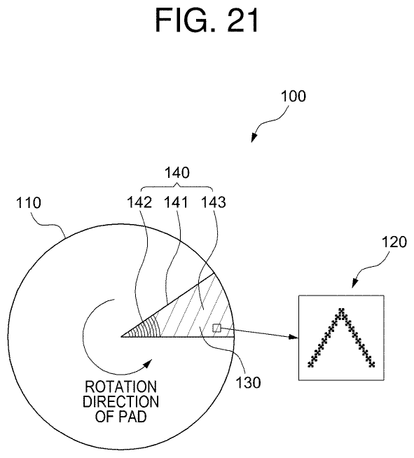

FIG. 25 is an exemplary view showing a chemical mechanical polishing pad having a pattern structure according to a third embodiment of the present invention.

Referring further to FIG. 25, a gap groove 3110 may be further formed on the upper pad part 1100.

The gap groove 3110 may be formed in the gap region, may be formed to have a preset depth toward the thickness direction of the upper pad part 1100, and may be made of a groove extending to the upper pad part 1100 or the lower pad part 1200 by a predetermined depth.

Here, the gap groove 3110 may be provided to have a width of 0.1 mm to 5 mm, a depth exceeding 0, and a thickness of the lower pad part under the gap groove 3110 is 0.01 mm or more.

As the gap groove 3110 is formed, the upper pad part 100 and the lower pad part 1200 are more flexibly deformed to correspond to the shape of the surface of the wafer, thereby further improving polishing efficiency.

However, the gap groove 3110 is not limited to being formed in the gap region, and may be formed on the upper pad part 1100 at a required position.

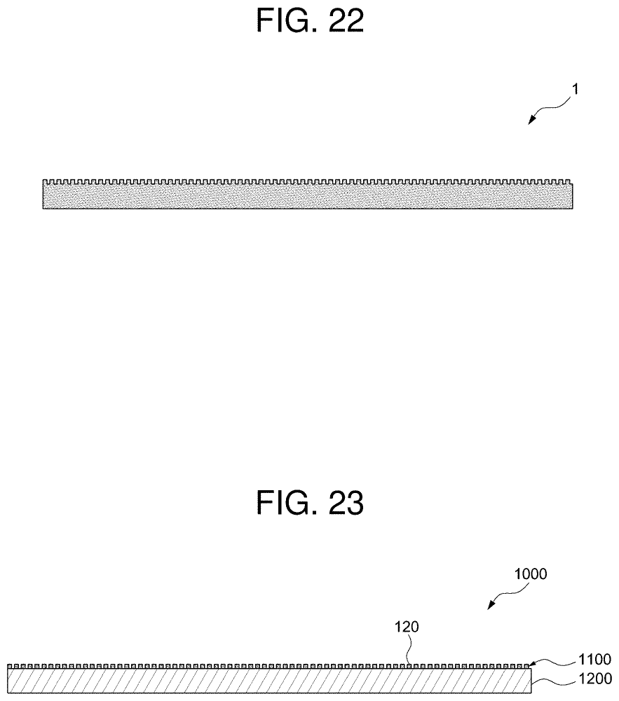

FIGS. 26 to 29 are exemplary views showing a chemical mechanical polishing pad having a pattern structure according to fourth to seventh embodiments of the present invention, and the chemical mechanical polishing pad having a pattern structure according to the fourth to seventh embodiments may be manufactured by forming the upper pad part on an adhesive film part and then attaching the upper pad part to the lower pad part.

In the case of forming the upper pad part on the adhesive film part in the fourth embodiment as shown in FIG. 26, the upper pad part 4100 may be formed by filling and freezing the engraved mold with a polymer in a similar manner to the above-described first embodiment, and since the figure unit and the pattern unit are the same as those of the first embodiment described above, a detailed description will be omitted.

In this case, in the process of forming the upper pad part on the adhesive film part, the upper pad part 4100 may be formed by a method of printing a thermoplastic polymer previously prepared in a sheet shape in a semi-melted state using the engraved mold. Accordingly, a freezing time may be shortened, so that a more rapid process may be performed, and in addition to the adhesive film, adhesion to the lower pad part may be better achieved.

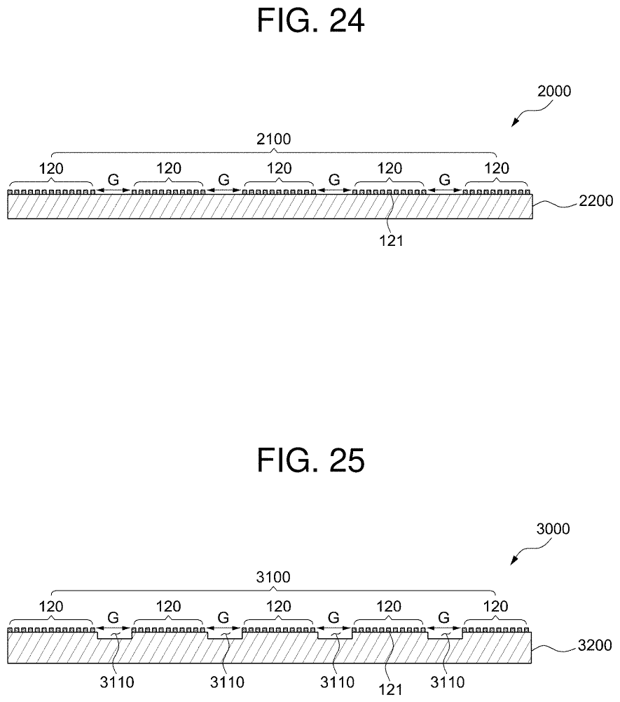

FIG. 27 is an exemplary view showing a chemical mechanical polishing pad having a pattern structure according to a fifth embodiment of the present invention, and the gap region (G) in which the figure unit 120 is not formed may be formed between a plurality of the pattern units.

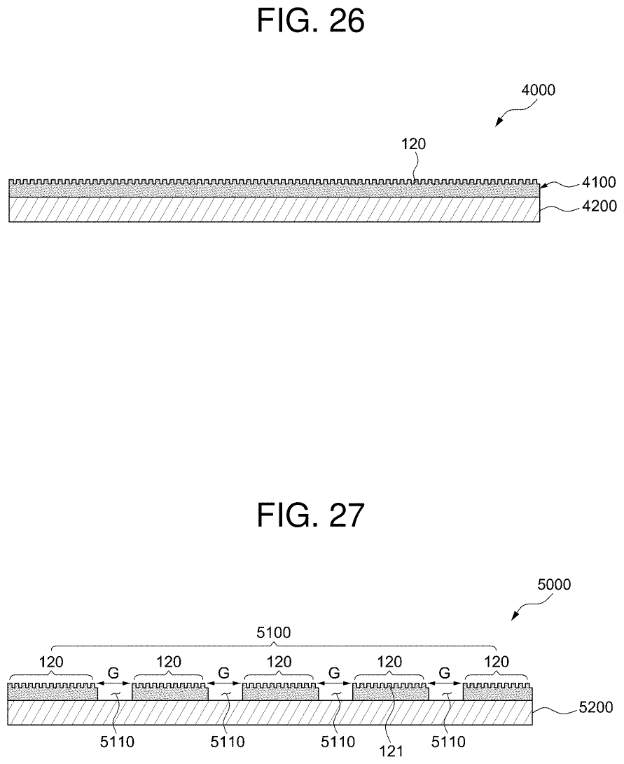

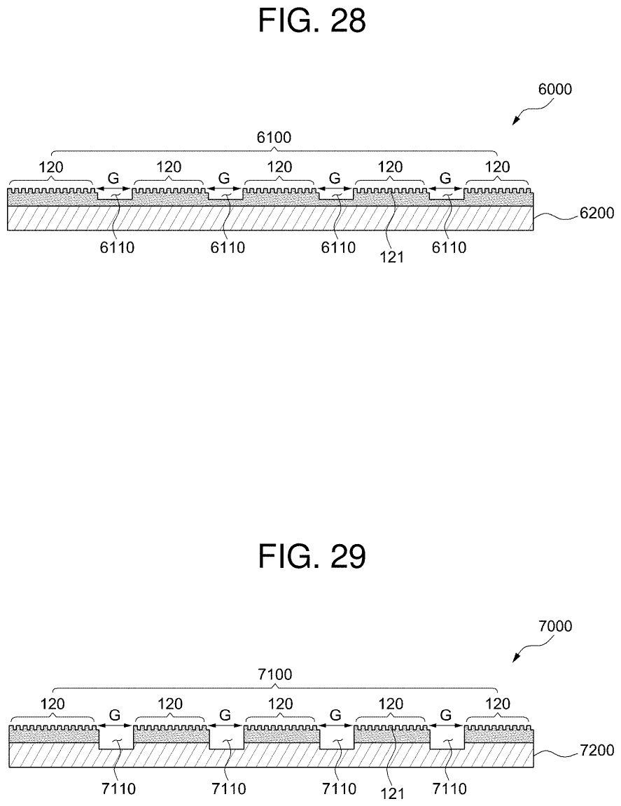

FIG. 28 is an exemplary view showing a chemical mechanical polishing pad having a pattern structure according to a sixth embodiment of the present invention, and FIG. 29 is an exemplary view showing a chemical mechanical polishing pad having a pattern structure according to a seventh embodiment of the present invention.

As shown in FIGS. 28 and 29, after the upper pad part and the lower pad part are adhered by using the adhesive film part, the gap groove may be further formed on the gap region or the upper pad part.

Specifically, as shown in FIG. 28, the gap groove 6110 may be formed to have a preset depth toward the thickness direction of the upper pad part 6100, and may be formed to form a groove extended to a predetermined depth of the upper pad part 6100.

Alternatively, as shown in FIG. 29, the gap groove 7110 may be formed to have a preset depth toward the thickness direction of the upper pad part 7100, and may be formed to form a groove extended to a predetermined depth of the upper pad part 7100 and the lower pad part 7200.

The gap groove 6110, 7110 provided as described above may allow the upper pad part 6100, 7100 and the lower pad part 6200, 7200 to be deformed to correspond to the surface shape of the wafer.

In addition, the gap groove according to the sixth and seventh embodiments may also be formed in the shape of the aforementioned groove unit.

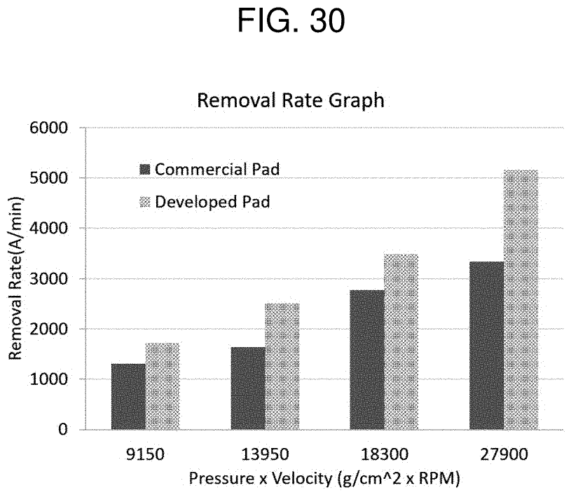

FIG. 30 is a graph comparing the polishing rate performances of a chemical mechanical polishing pads having a pattern structure manufactured according to the present invention and a conventional polishing pad. As such, it can be seen that the present invention has an improved polishing rate performance under various conditions compared to the conventional polishing pad.

In addition, the method for manufacturing a chemical mechanical polishing pad having a pattern structure of the present invention is only an embodiment for manufacturing a chemical mechanical polishing pad having a pattern structure, and is not limited to the above-described method.

Specifically, it can also be manufactured by directly engraving (removal manufacturing method) on a material by a method such as laser, e-beam, etching, etc. In addition, it is possible to make it directly using a 3D printer without using a mold.

The above description of the present invention is for illustrative purposes only, and those of ordinary skill in the art to which the present invention pertains will be able to understand that this can be easily modified into other specific forms without changing the technical spirit or essential features of the present invention. Therefore, it should be understood that the embodiments described above are illustrative in all respects and not limiting. For example, each component described as a single type may be implemented in a dispersed manner, and similarly, components described as being dispersed may also be implemented in a combined form.

The scope of the present invention is indicated by the claims to be described later, and all changes or modified forms derived from the meaning and scope of the claims and their equivalent concepts should be interpreted as being included in the scope of the present invention.

### EXPLANATION OF NUMERAL REFERENCES

100: pad for polishing
110: polishing pad
120: figure unit
121: single figure part
122: continuous figure part
123: set figure part
130: pattern unit
140: groove unit
141: first groove
142: second groove
143: third groove
1000: chemical mechanical polishing pad having a pattern structure according to a first embodiment
2000: chemical mechanical polishing pad having a pattern structure according to a second embodiment
3000: chemical mechanical polishing pad having a pattern structure according to a third embodiment
4000: chemical mechanical polishing pad having a pattern structure according to a fourth embodiment
5000: chemical mechanical polishing pad having a pattern structure according to a fifth embodiment
6000: chemical mechanical polishing pad having a pattern structure according to a sixth embodiment
7000: chemical mechanical polishing pad having a pattern structure according to a seventh embodiment
1100, 2100, 3100, 4100, 5100, 6100, 7100: upper pad part
1200, 2200, 3200, 4200, 5200, 6200, 7200: lower pad part
3110, 5110, 6110, 7110: gap groove
G: gap region

What is claimed is:

1. A chemical mechanical polishing pad having a pattern structure, comprising:
a polishing pad configured to polish a wafer placed thereon; and
a plurality of figure units formed on the polishing pad and formed to protrude from an upper portion of the polishing pad,
wherein the figure units are formed to have a predetermined contact area ratio and a predetermined circumferential length per unit area which correspond to a target polishing characteristic.

2. The chemical mechanical polishing pad having a pattern structure according to claim 1, wherein the contact area ratio is a value obtained by dividing a total protruding area (Aᵤ) of figure units of the plurality of figure units included in an inspection area by the inspection area (A₀) in a plan view.

3. The chemical mechanical polishing pad having a pattern structure according to claim 2, wherein the circumferential length per unit area is a value obtained by dividing a total circumferential length (Lₜ) of the figure units included in the inspection area by the inspection area (A₀).

4. The chemical mechanical polishing pad having a pattern structure according to claim 3, wherein the contact area ratio is 1.0% to 80.0%, and the circumferential length per unit area is 1 mm/mm² to 250 mm/mm².

5. The chemical mechanical polishing pad having a pattern structure according to claim 1, wherein the figure units include at least one type of a single figure part, a continuous figure part, and a set figure part,
the single figure part is surrounded by one single closed curve,
the continuous figure part is formed by a continuous line without the single closed curve and is composed of a minimum unit of repetition of the continuous line, and
the set figure part is composed of a set of a plurality of the single figure parts adjacent to each other that is a minimum unit of repetition.

6. The chemical mechanical polishing pad having a pattern structure according to claim 5, wherein the single figure part is provided in plural, and the figure units are provided by uniformly and repeatedly arranging the single figure parts of a same shape on the polishing pad.

7. The chemical mechanical polishing pad having a pattern structure according to claim 5, wherein the single figure part is provided in plural, and the figure units are provided by uniformly and repeatedly arranging the single figure parts of different shapes on the polishing pad.

8. The chemical mechanical polishing pad having a pattern structure according to claim 5, wherein the single figure part is provided in plural, and the figure units are provided by irregularly and repeatedly arranging the single figure parts of different shapes on the polishing pad.

9. The chemical mechanical polishing pad having a pattern structure according to claim 5, wherein the single figure part is provided in plural, and the figure units are provided by repeatedly arranging the single figure parts of a same shape with different sizes on the polishing pad.

10. The chemical mechanical polishing pad having a pattern structure according to claim 1, further comprising a plurality of pattern units including the plurality of figure units.

11. The chemical mechanical polishing pad having a pattern structure according to claim 10, wherein each of the plurality of pattern units has a sector shape on the polishing pad.

12. The chemical mechanical polishing pad having a pattern structure according to claim 11, wherein the pattern units are provided by dividing the polishing pad into a number of pieces such that a flow direction of a polishing liquid in each of the pattern units according to a rotation direction of the polishing pad becomes the same in order to achieve uniform polishing in which a polishing characteristic of the wafer satisfies a preset error rate in an entirety of the polishing pad.

13. The chemical mechanical polishing pad having a pattern structure according to claim 11, wherein the figure units are arranged such that polishing liquid flowing according to a rotation direction moves toward an upper portion of the figure units.

14. The chemical mechanical polishing pad having a pattern structure according to claim 5, wherein the figure units are arranged to prevent polishing liquid flowing into the set figure part and the continuous figure part from flowing out of the polishing pad.

15. The chemical mechanical polishing pad having a pattern structure according to claim 10, further comprising a groove unit that is formed on the pattern units and is provided in a groove shape to transfer polishing liquid supplied to the pattern units to a front surface of the pattern units.

16. The chemical mechanical polishing pad having a pattern structure according to claim 15, wherein the groove unit includes a first groove radially formed along borders between the pattern units to guide the polishing liquid in a direction from a center of the polishing pad to an edge of the polishing pad.

17. The chemical mechanical polishing pad having a pattern structure according to claim 16, wherein the pattern units are formed so that the number of the first groove is 3 to 12.

18. The chemical mechanical polishing pad having a pattern structure according to claim 15, wherein the groove unit includes a plurality of second grooves that is formed in a concentric shape forming a concentric circle on the polishing pad to guide the polishing liquid along the concentric shape.

19. The chemical mechanical polishing pad having a pattern structure according to claim 18, wherein the plurality of second grooves are provided to have an interval of 0.5 mm to 5 mm.

20. The chemical mechanical polishing pad having a pattern structure according to claim 15, wherein the groove unit includes a third groove that is formed inclined with respect to a direction tangential to a rotation direction of the polishing pad.

21. The chemical mechanical polishing pad having a pattern structure according to claim 20, wherein the third groove is formed inclined to +45 degrees to −45 degrees with respect to the tangent direction of the rotation direction of the polishing pad.

22. The chemical mechanical polishing pad having a pattern structure according to claim 15, wherein the groove unit is provided to have a width of 0.1 mm to 2.0 mm, and is formed to have a depth of 0.05 mm to 2.00 mm.

23. The chemical mechanical polishing pad having a pattern structure according to claim 15, wherein the groove unit is provided to have at least one of a first groove, a second groove, and a third groove.

24. The chemical mechanical polishing pad having a pattern structure according to claim 1, wherein the polishing pad is composed of an upper pad part and a lower pad part, the lower pad part is formed such that at least one physical property of hardness and elastic modulus is lower than a corresponding property of the upper pad part.

25. The chemical mechanical polishing pad having a pattern structure according to claim 24, wherein the upper pad part is formed directly on the lower pad part and is provided in an integrated state with the lower pad part.

26. The chemical mechanical polishing pad having a pattern structure according to claim 24, wherein a pattern unit composed of the plurality of figure units is formed on the upper pad part.

27. The chemical mechanical polishing pad having a pattern structure according to claim 26, wherein the pattern unit is provided in plural, and the upper pad part is provided to form a gap region in which no figure unit is formed and which is located between the plurality of the pattern units.

28. The chemical mechanical polishing pad having a pattern structure according to claim 27, wherein a width of the gap region is 0.2 mm to 5 mm.

29. The chemical mechanical polishing pad having a pattern structure according to claim 26, wherein a gap groove is further formed on the upper pad part, and the gap groove is formed to have a preset depth toward a thickness direction of the upper pad part, and is composed of a groove extended to the upper pad part or the lower pad part.

30. The chemical mechanical polishing pad having a pattern structure according to claim 29, wherein the gap groove is formed to have a width of 0.1 mm to 5 mm, and a depth exceeding 0 mm, and a thickness of the lower pad part under the gap groove is 0.01 mm or more.

31. The chemical mechanical polishing pad having a pattern structure according to claim 26, wherein a protrusion height of the figure units is 0.001 mm to 1 mm.

32. The chemical mechanical polishing pad having a pattern structure according to claim 26, wherein an amount of change in a cross-sectional area in a vertical direction of the figure units is provided to be 0 to 20%.

33. The chemical mechanical polishing pad having a pattern structure according to claim 24, wherein a total thickness of the upper pad part and the lower pad part is formed to be less than 5 mm.
